(19) United States
(12) Patent Application Publication
(10) Pub. No.: US 2026/0198388 A1
(43) Pub. Date: Jul. 9, 2026

(54) Semiconductor Device and Method of Making a Molded Interposer with an Embedded Bridge Module

(71) Applicant: STATS ChipPAC Management Pte. Ltd., Singapore (SG)

(72) Inventors: TaeWoo Lee, Incheon (KR); HeeSoo Lee, Incheon (KR); EunHee Myung, Gyeonggi-do (KR)

(73) Assignee: STATS ChipPAC Management Pte. Ltd., Singapore (SG)

(21) Appl. No.: 19/010,532

(22) Filed: Jan. 6, 2025

(51) Int. Cl. H01L 23/498; H01L 21/56; H01L 23/31

(52) U.S. Cl. CPC H10W 90/701; H10W 70/635; H10W 74/01; H10W 74/10

(57) ABSTRACT

A semiconductor device has a bridge die. An electrical component is mounted to the bridge die to form a bridge module. The bridge module is disposed over a carrier. A conductive via is formed over the carrier. An encapsulant is deposited over the conductive via and bridge module. A first conductive layer is formed over the encapsulant, conductive via, and bridge module. The carrier is removed. A second conductive layer is formed over the encapsulant, conductive via, and bridge module opposite the first conductive layer. A first semiconductor die and second semiconductor die are disposed over the bridge module and encapsulant. The first semiconductor die is coupled to the second semiconductor die through the bridge die.

### FIELD OF THE INVENTION

The present invention relates in general to semiconductor devices and, more particularly, to semiconductor devices and methods of making a molded interposer with an embedded bridge module.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. At the same time, more and more complex semiconductor devices are demanded by device manufacturers. Bridge die can be embedded within semiconductor substrates to provide a tighter pitch of interconnect and higher total bandwidth than the substrate itself can provide. However, continually shrinking end devices requires even more advanced integration. Therefore, a need exists for improved semiconductor devices and methods of making bridge modules and chiplet structures having the bridge modules.

### BRIEF DESCRIPTION OF THE DRAWINGS

FIGS. 1a-1j illustrate the formation of a first bridge module embodiment;

FIGS. 2a-2f illustrate the formation of a second bridge module embodiment;

FIGS. 3a-3l illustrate forming a molded interposer with the second bridge module embodiment;

FIG. 4 illustrates a chiplet formed using the molded interposer with the second bridge module embodiment;

FIGS. 5a-5c illustrate an alternative method of forming a molded interposer;

FIG. 6 illustrates a chiplet formed using the alternative molded interposer and the second bridge module embodiment;

FIG. 7 illustrates a chiplet formed using a molded interposer with the first bridge module embodiment; and

FIGS. 8a and 8b illustrate an electronic device with the chiplets.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

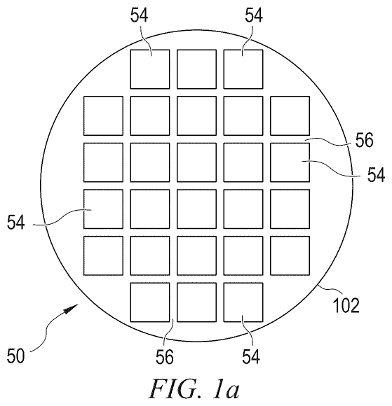

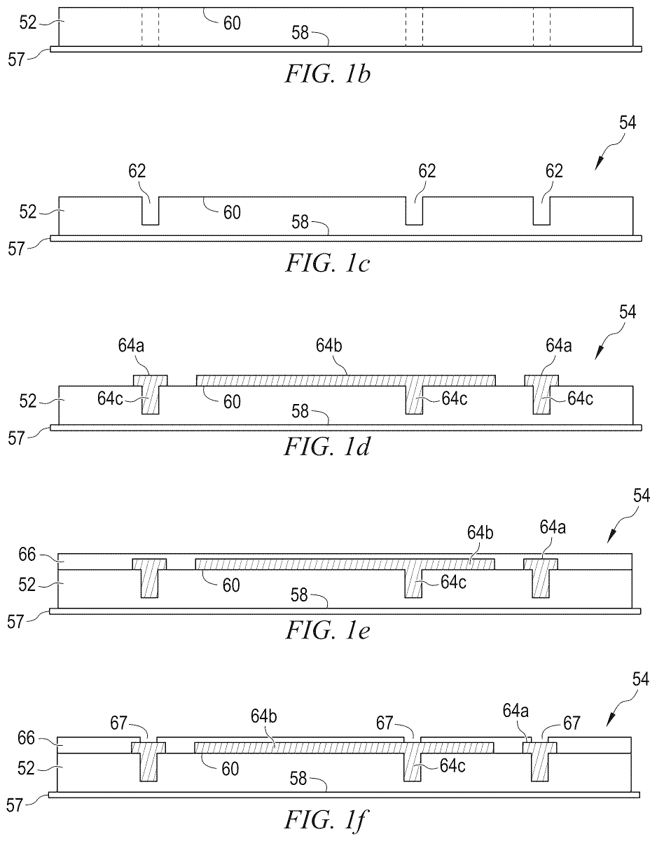

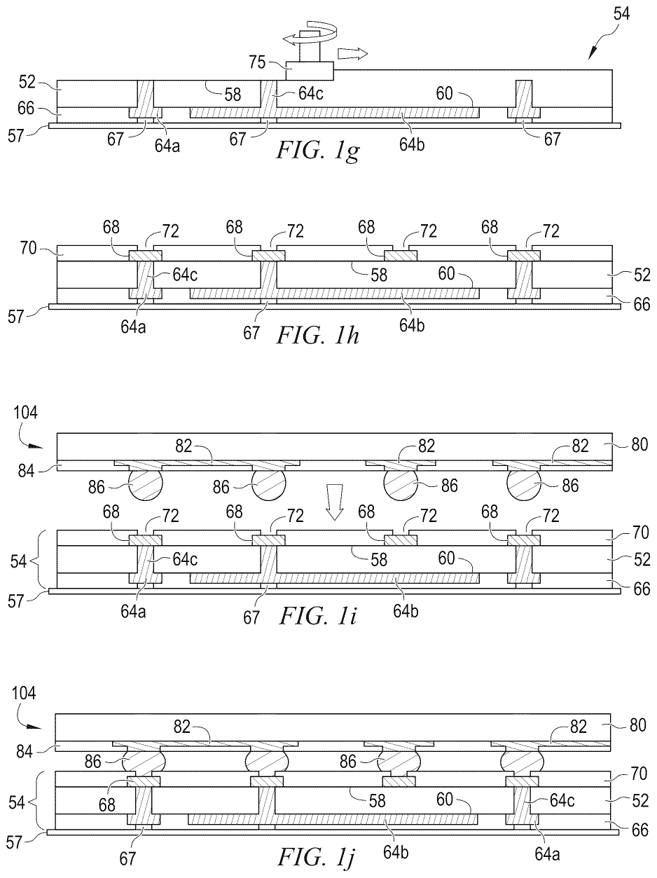

FIGS. 1a-1j illustrate a process of forming a bridge module for inclusion in a chiplet design. FIG. 1a shows a semiconductor wafer 50 with a base substrate material 52, such as silicon, germanium, aluminum phosphide, aluminum arsenide, gallium arsenide, gallium nitride, indium phosphide, silicon carbide, or other bulk material for structural support. Non-silicon substrates are used in other embodiments, e.g., glass, insulating material, or a PCB material. Semiconductor materials are more commonly used due to the maturity of manufacturing processes for forming fine pitched interconnects on silicon.

A plurality of bridge die 54 is formed on wafer 50 separated by a non-active, inter-die wafer area or saw street 56. Saw street 56 provides cutting areas to singulate semiconductor wafer 50 into individual bridge die 54. Wafer 50 begins as a single uniform body of semiconductor material. FIG. 1b shows a cross-sectional view of a portion of semiconductor material 52 at the beginning of the process of forming a bridge die 54. Wafer 50 is placed on a carrier 57 for processing.

In FIG. 1c, a plurality of openings 62 is formed into bridge die 54 at locations where conductive vias are desired for vertical electrical interconnect through the bridge die. Openings 62 are formed by deep reactive-ion etching (DRIE), mechanical drilling, chemical etching, or another suitable means. Openings 62 are formed only partially through bridge die 54. In other embodiments, openings 62 are formed completely through bridge die 54.

A conductive layer 64 is formed over surface 60 of semiconductor wafer 50 in FIG. 1d. Conductive layer 64 is formed using physical vapor deposition (PVD), chemical vapor deposition (CVD), electrolytic plating, electroless plating, sputtering, or other suitable metal deposition process. Conductive layer 64 can be one or more layers of aluminum (Al), copper (Cu), tin (Sn), nickel (Ni), gold (Au), silver (Ag), or other suitable electrically conductive material. Any conductive layer described above or below can be formed using the same methods and materials as conductive layer 64.

Conductive layer 64 is patterned to include contact pads 64a and conductive traces 64b. The conductive material of conductive layer 64 also fills openings 62 to form conductive vias 64c into or through bridge die 54. To operate as a bridge die, bridge die 54 includes contact pads 64a near two opposing edges of each bridge die, each being paired with a contact pad on the opposite edge of the bridge die 54 by a conductive trace 64b. Those contact pads 64a paired across bridge die 54 by a conductive trace 64b will ultimately provide fine-pitched electrical interconnect between two overlying functional semiconductor die in a chiplet or other type of semiconductor package, i.e., operate as an interconnect bridge.

When bridge die 54 is incorporated into a semiconductor package, e.g., a chiplet or system-in-package, two other semiconductor die will be disposed over the opposing edges of bridge die 54. Each overlying semiconductor die will be connected to one side of bridge die 54 using contact pads 64a, and then the bridge die will interconnect the two overlying semiconductor die to each other by conductive traces 64b. Other contact pads 64a are optionally formed for electrical interconnect to other components within the bridge module being formed and not necessarily for interconnect between two other die.

In FIG. 1e, a passivation or solder resist layer 66 is formed over conductive layer 64 to protect the conductive layer. Solder resist layer 66 can be formed using any of the methods and materials described below for insulating layers generally. Openings 67 are formed through solder resist layer 66 in FIG. 1f using chemical etching, photolithography, laser ablation, or another suitable means, to expose contact pads 64a.

In FIG. 1g, bridge die 54 is flipped and returned to carrier 57 or another suitable carrier with surface 58 exposed for further processing. A grinder 76, or another suitable means, is used to remove a portion of semiconductor material over conductive vias 64c to expose the conductive vias for subsequent electrical interconnect if necessary.

In FIG. 1h, a conductive layer 68 is formed over surface 58 of semiconductor wafer 50. Conductive layer 68 is formed using the methods and materials described above for conductive layer 64. Conductive layer 68 is patterned to include contact pads and, in some embodiments, conductive traces extending between the contact pads. Solder resist layer 70 is formed over conductive layer 68 as described above for solder resist layer 66. Openings 72 are formed through solder resist layer 70 to expose contact pads of conductive layer 68 for subsequent electrical interconnect.

In some embodiments, opposing surfaces 58 and 60 optionally contain analog or digital circuits implemented as active devices, passive devices, conductive layers, and dielectric layers formed on or within the die and electrically interconnected according to the electrical design and function of the die. For example, the circuits may include one or more transistors, diodes, and other circuit elements formed within surfaces 58 or 60 to implement analog circuits or digital circuits, such as a digital signal processor (DSP), application specific integrated circuit (ASIC), memory, or other signal processing circuit. Bridge die 54 may also contain IPDs, such as inductors, capacitors, and resistors, for RF signal processing. In other embodiments, bridge die 54 contain no active or passive components, except for conductive layer 64 being formed over surface 60 and conductive layer 68 being formed over surface 58.

In FIG. 1i, another electrical component 80 is disposed over bridge die 54 and mounted to the bridge die in FIG. 1j. Electrical component 80 is a semiconductor die with active circuits interconnected by conductive layer 82 in one embodiment. In other embodiments, electrical component 80 has passive circuits formed as IPDs within conductive layers formed over the semiconductor die with or without active components formed in the die. Electrical component 80 can be any suitable electrical component or combination of electrical components, including semiconductor die, semiconductor packages, system-in-package (SiP) modules, a chiplet, active or passive discrete components, or any combination thereof. A solder resist or passivation layer 84 is formed over conductive layer 82 as described above for solder resist layers 66 and 70.

Solder bumps 86 or another suitable interconnect structure is formed on contact pads of conductive layer 82. An electrically conductive bump material is deposited over conductive layer 82 in openings of insulating layer 84 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 82 using a suitable attachment or bonding process. In one embodiment, the bump material is reflowed by heating the material above its melting point to form balls or bumps 86. In one embodiment, bump 86 is formed over an under-bump metallization (UBM) having a wetting layer, a barrier layer, and an adhesion layer.

A bridge module 104 is completed in FIG. 1j by reflowing bumps 86 to mechanically and electrically couple electrical component 80 to bridge die 54. Bridge die 54, and electrical component 80 if necessary, can be singulated prior to mounting in FIG. 1j using a saw blade or laser cutting tool. In other embodiments, electrical component 80 is an individual component at the die level mounted on wafer 50 prior to singulation of the wafer, or components 80 are mounted as a wafer onto wafer 50 and both wafers are singulated together. In some embodiments, multiple electrical components 80 are mounted onto each bridge die 54 to form a single module. The plurality of electrical components 80 can have different functions, e.g., one component for passive components and a second component for active components.

Bridge module 104 includes a bridge die 54 to provide interconnect between two overlying semiconductor die, and electrical component 80 to provide supplemental electrical functionality for the overlying semiconductor die. An optional encapsulant or underfill can be deposited between bridge die 54 and electrical component 80.

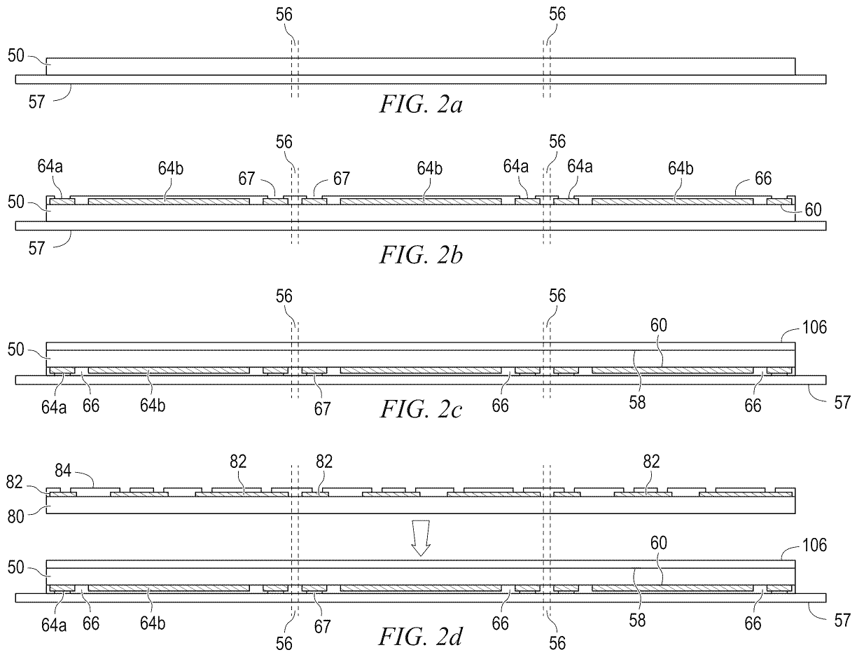

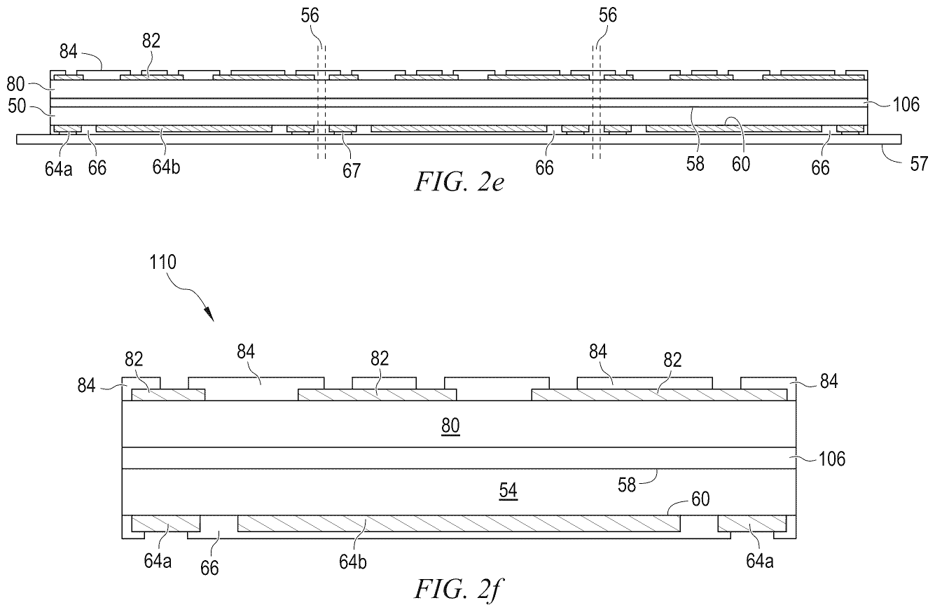

FIGS. 2a-2f illustrate another embodiment of forming a bridge module. Wafer 50 is disposed on carrier 57 in FIG. 2a. In FIG. 2b, conductive layer 64 with fine-pitched interconnects is formed as described above, including conductive traces 64b that connect from contact pads 64a on one side of each bridge die 54 to contact pads on the opposite side. Without prior-formed vias, conductive layer 64 does not form conductive vias as in module 104. Solder resist layer 66 is formed as described above, with openings 67 to expose contact pads 64a.

In FIG. 2c, wafer 50 is flipped over on carrier 57, or onto a different carrier, so that surface 58 is oriented up. An adhesive layer 106 is disposed or deposited onto surface 58. Adhesive layer 106 can be a sheet of adhesive, a liquid adhesive, a double-sided tape, or any other suitable type of adhesive. In FIG. 2d, a panel or wafer of electronic components 80 is disposed over wafer 50 with conductive layer 82 oriented away from the bottom wafer. The back surfaces of electronic components 80 and wafer 50 are attached to each other by adhesive 106 when the electronic component is set down in FIG. 2e. Bridge die 54, electronic component 80, or both can be attached at the die level instead of as a wafer.

The combination of wafer 50 and electronic components 80 is singulated using a saw blade or laser cutting tool to complete a bridge module 110 in FIG. 2f. Bridge module 110 includes a bridge die 54 connectable from one side of the bridge module and an electronic component 80 connectable from the opposite side. As with bridge die 104, multiple electrical components 80 of any suitable type and combination can be used for each bridge module 110.

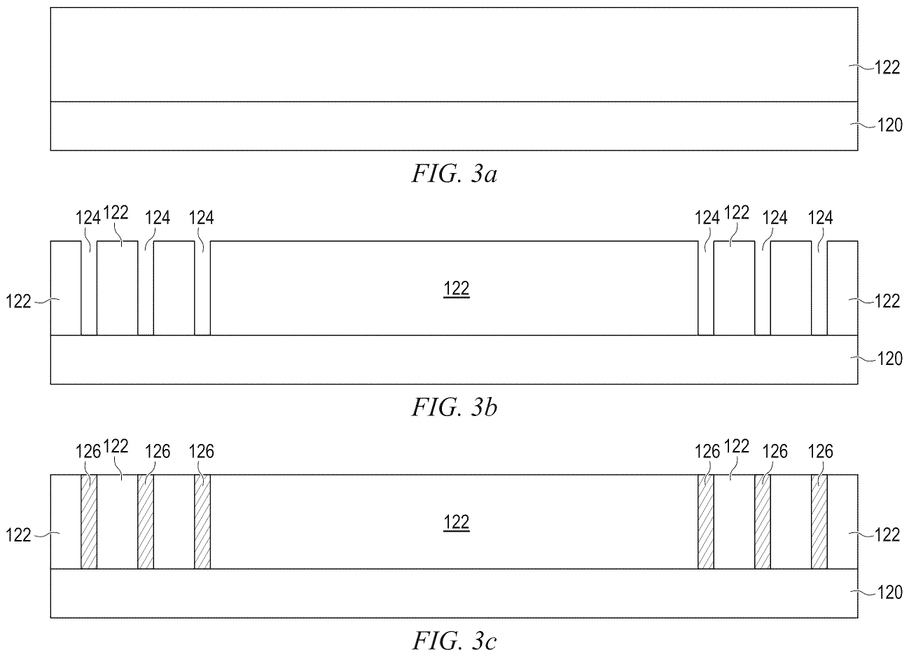

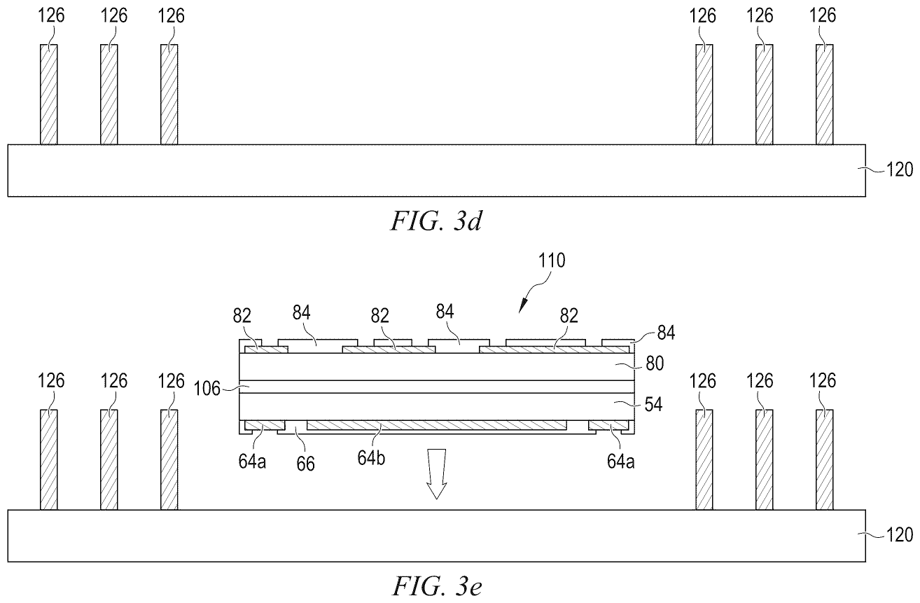

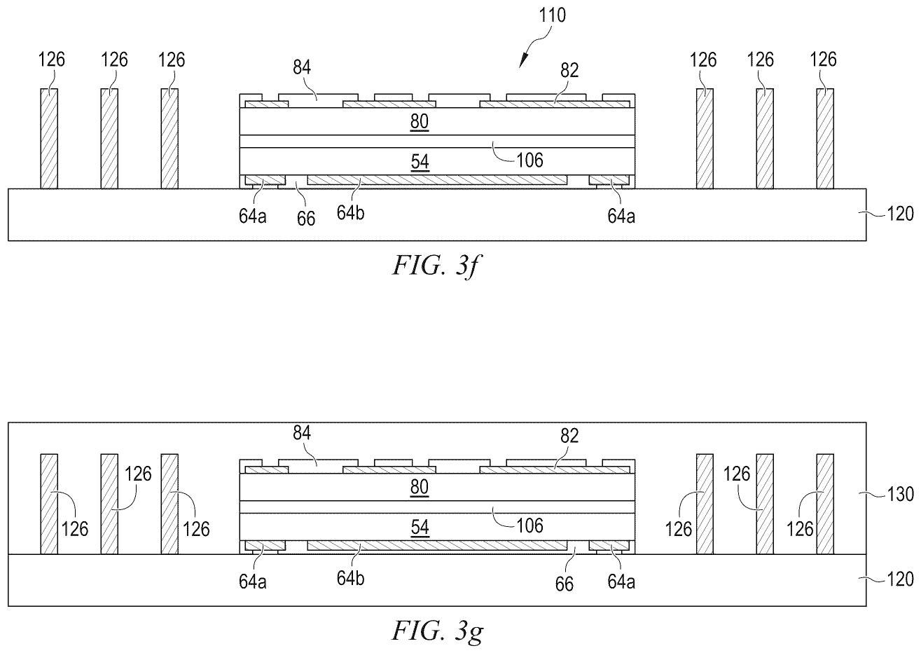

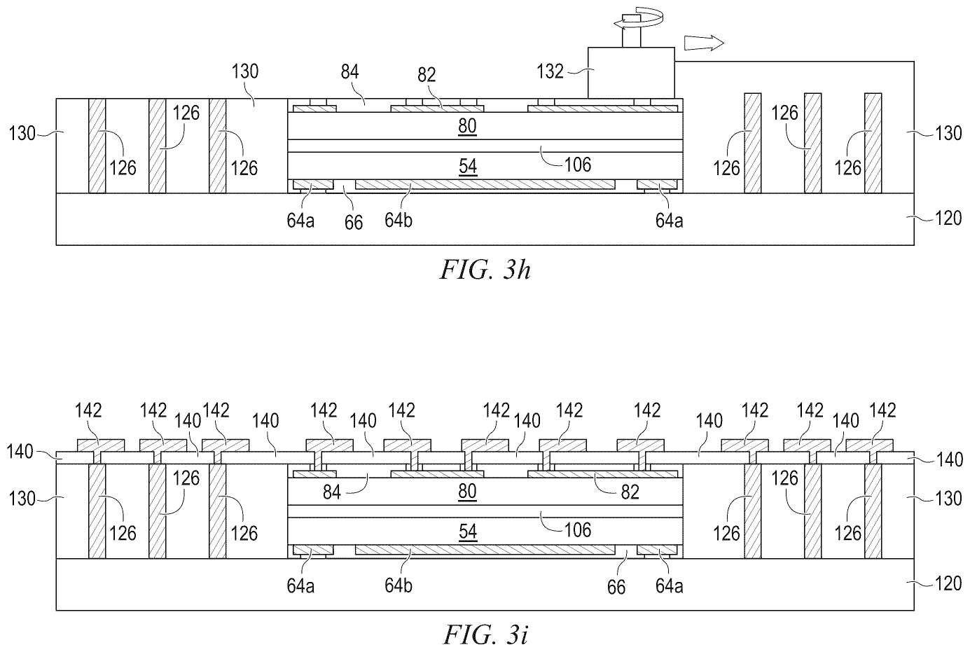

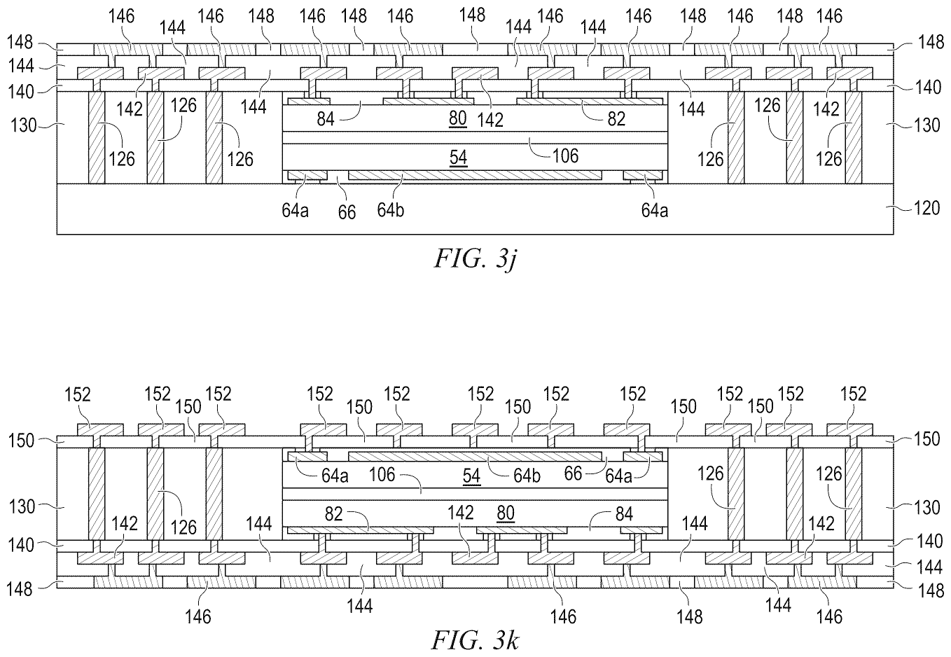

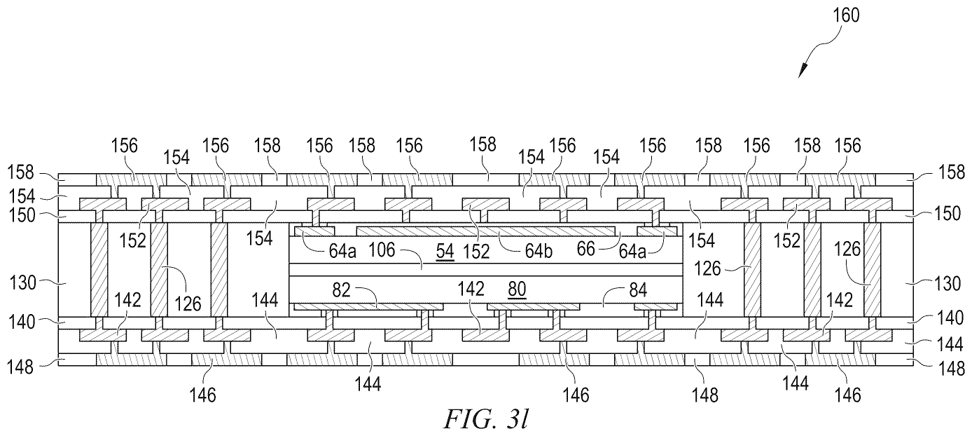

FIGS. 3a-3l illustrate forming a molded interposer with an embedded bridge module. FIG. 3a shows a carrier 120 and a photoresist layer 122 formed over the carrier. Photoresist layer 122 can be formed using a photoresist material, or any other suitable insulating material. Photoresist layer 122 is used as a mask by forming openings 124 through the photoresist layer in FIG. 3b. Openings 124 can be formed using chemical etching, photolithography, mechanical drilling, laser drilling, or another suitable means. Openings 124 are formed at locations where conductive vias through the molded interposer are desired. Openings are formed completely through photoresist layer 122 but could also be formed only partially into the photoresist layer.

Conductive vias 126 are formed in FIG. 3c by depositing conductive material into openings 124. The conductive material can be any material discussed above or below for conductive layers, e.g., copper, and deposited using any suitable metal deposition technique. Openings 124 can be completely filled with conductive material for conductive vias 126, or only coated with a thin layer while remaining hollow. Conductive vias 126 included a circular cross-section in plan view but can be formed in any other desired shape. Conductive vias 126 can be formed as conductive posts using any suitable means, including being pre-formed before being disposed onto carrier 120.

In FIG. 3d, photoresist layer 122 is removed using a chemical wash or other suitable means to leave conductive vias 126 extending upward from carrier 120. In FIG. 3e, a bridge module 110 is disposed onto carrier 120 using a pick-and-place machine or other suitable means. Bridge die 54 is oriented toward carrier 120, but bridge module 110 could also be disposed upside-down relative to the illustration. FIG. 3f shows bridge module 110 disposed on carrier 120 between conductive vias 126.

A molding compound or encapsulant 130 is deposited over carrier 120, bridge module 110, and conductive vias 126 in FIG. 3g. Encapsulant 130 is deposited using a paste printing, compression molding, transfer molding, liquid encapsulant molding, vacuum lamination, spin coating, or other suitable applicator. Encapsulant 130 can be liquid or granular polymer composite material, such as epoxy resin, epoxy acrylate, or another suitable polymer, with or without a filler. Encapsulant 130 is non-conductive, provides structural support, and environmentally protects the semiconductor device from external elements and contaminants.

Encapsulant 130 is deposited to completely cover the top surfaces of bridge module 110 and conductive vias 126. In other embodiments, film-assisted molding or another technique is used to deposit encapsulant 130 with conductive pillars and bridge module 110 remaining exposed from the encapsulant. In FIG. 3h, a grinder 132 or other suitable mechanism is used to remove the portion of encapsulant 130 over conductive vias 126 and bridge module 110. In some embodiments, a portion of conductive vias 126 is removed as well to ensure the vias are exposed. After grinding, the top surfaces of conductive vias 126, encapsulant 130, and bridge module 110 are coplanar. In other embodiments, conductive vias 126 are formed through openings in encapsulant 130 after deposition of the encapsulant.

Next, a build-up interconnect structure is formed over the panel of encapsulant 130, beginning with an insulating layer 140 and conductive layer 142 being formed in FIG. 3i. Insulating layer 140 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Insulating layer 140 can be formed using PVD, CVD, printing, lamination, spin coating, spray coating, sintering, or thermal oxidation.

Any insulating layer, passivation layer, dielectric layer, underfill, or encapsulant mentioned above or below can be formed using any of the materials or methods described for insulating layer 140 or encapsulant 130. Openings are formed through insulating layer 140, and any remaining portions of encapsulant 130 and insulating layer 84 remaining over electrical component 80, to expose contact pads of conductive layer 82. The openings can be formed by chemical etching, photolithography, mechanical drilling, laser drilling, or any other suitable means. In some embodiments, a conductive layer is formed first, and then insulating layer 140 is formed.

A conductive layer 142 is formed on insulating layer 140 and through the openings in the insulating layer to physically and electrically couple to conductive layer 82 and conductive vias 126. Conductive layer 142 includes conductive traces to fan-out or fan-in from conductive layer 82 and conductive vias 126, and optionally contact pads at both ends of the traces for connecting to the underlying contacts and for subsequent formation of overlying conductive structures. Conductive layer 142 is formed using PVD, CVD, electrolytic plating, electroless plating, sputtering, or other suitable metal deposition process. Conductive layer 142 can be one or more layers of Al, Cu, Sn, Ni, Au, Ag, or other suitable electrically conductive material. Any conductive layer described above or below can be formed using the same materials and methods described for conductive layer 142.

In FIG. 3j, another insulating layer 144 and conductive layer 146 are formed over insulating layer 140 and conductive layer 142. Insulating layer 144 is formed as described above for insulating layer 140. Conductive layer 146 is formed as described above for conductive layer 142. Any number of conductive layers and insulating layers are interleaved over encapsulant 130 as needed to implement the desired electrical signal routing. In the illustrated embodiments, two conductive layers 142 and 146 are formed for signal routing with two insulating layers 140 and 142 formed to support the conductive layers, respectively. Each successive conductive layer is formed through openings of an underlying insulating layer to electrically connect vertically through the build-up interconnect structure. Any suitable number of insulating and conductive layers can be used to implement the desired signal routing, including only a single conductive layer.

After the desired number of conductive layers and insulating layers have been built up, contact pads or under-bump metallization (UBM) pads are optionally formed on the top conductive layer. UBM pads are optionally formed of multiple conductive layers including a wetting layer, barrier layer, and adhesion layer. A passivation or solder resist layer 148 is optionally formed over the top contact pad or UBM layer. Passivation layer 148 is formed of materials using methods as described above for insulating layers generally. Openings are formed in passivation layer 148 to expose contact pads or UBM pads for subsequent electrical interconnect. UBM pads can have a flat top surface as illustrated or be formed conformally in openings of passivation layer 148 or insulating layer 144.

In FIG. 3k, the panel of bridge modules 110 embedded in encapsulant 130 is flipped so that bridge die 54 is oriented upward. Insulating layer 150 and conductive layer 152 are formed over encapsulant 130 as described above for insulating layer 140 and conductive layer 142. In FIG. 3l, a molded interposer 160 is completed by forming insulating layer 154, conductive layer 156, and passivation layer 158 over insulating layer 150 and conductive layer 152. Insulating layer 154 is formed as described above for insulating layer 140. Conductive layer 156 is formed as described above for conductive layer 142. Passivation layer 158 is formed as described above for passivation layer 148. The individual portions of conductive layers 142, 146, 152, and 156 can be electrically connected or electrically isolated from each other according to the intended electrical design of the molded interposer being formed.

Molded interposer 160 is an interposer or substrate usable to form a semiconductor package or chiplet. Molded interposer 160 has an embedded bridge module 110. Bridge module 110 has a bridge die 54 providing fast and high-density electrical interconnect and an electrical component 80 providing additional electrical functionality. Molded interposer 160 can remain as a larger panel with a plurality of units attached together, or the molded interposer can be singulated into a plurality of the units shown in FIG. 3l. Molded interposer 160 is typically completed and then provided to a semiconductor packaging company as a panel, before being singulated with the completed packages. In other embodiments, the same company immediately forms a chiplet or other semiconductor package with a completed molded interposer 160.

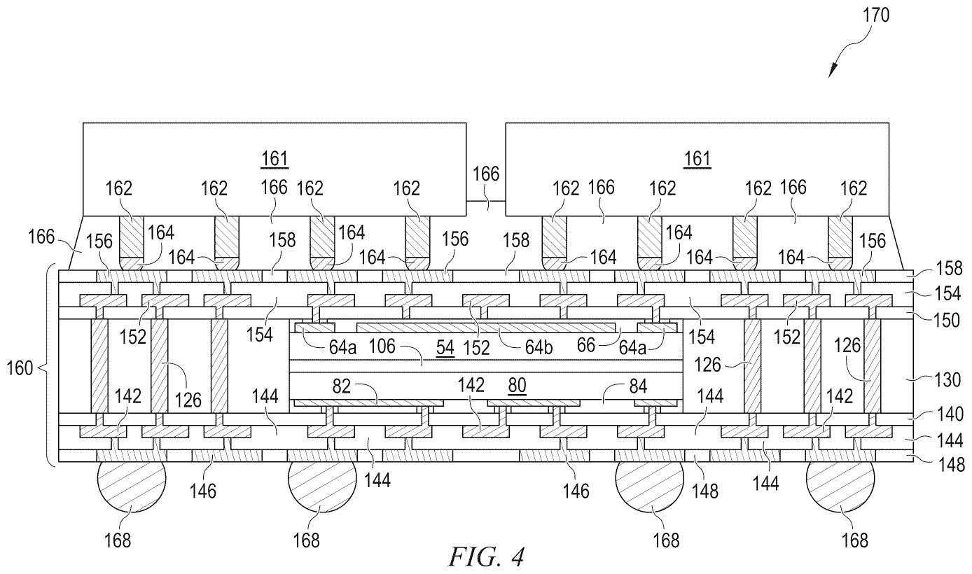

FIG. 4 illustrates one example of a chiplet 170 formed on molded interposer 160. A pair of semiconductor die 161 is mounted onto conductive layer 156 and electrically interconnected to molded interposer 160 through conductive pillars 162 and solder bumps 164. Bumps 164 are reflowed to mechanically and electrically attach conductive pillars 162 to conductive layer 156. An underfill 166 is deposited under and between semiconductor die 161 to physically support the semiconductor die. In some embodiments, the area between semiconductor die 161 is completely filled with underfill 166, with the underfill having a top surface coplanar to the semiconductor die. Each semiconductor die 161 is electrically coupled to an opposite side of bridge die 54, and to each other through the bridge die. In addition, semiconductor die 161 are electrically coupled to conductive vias 126. The enhanced integration provided by embedding bridge die 54 as part of bridge module 110 having electrical component 80 attached reduces manufacturing complexity and cost while increasing functionality. Solder bumps 168, or interconnect structures of another suitable type, are optionally formed on contact pads of conductive layer 146 as described above for bumps 86.

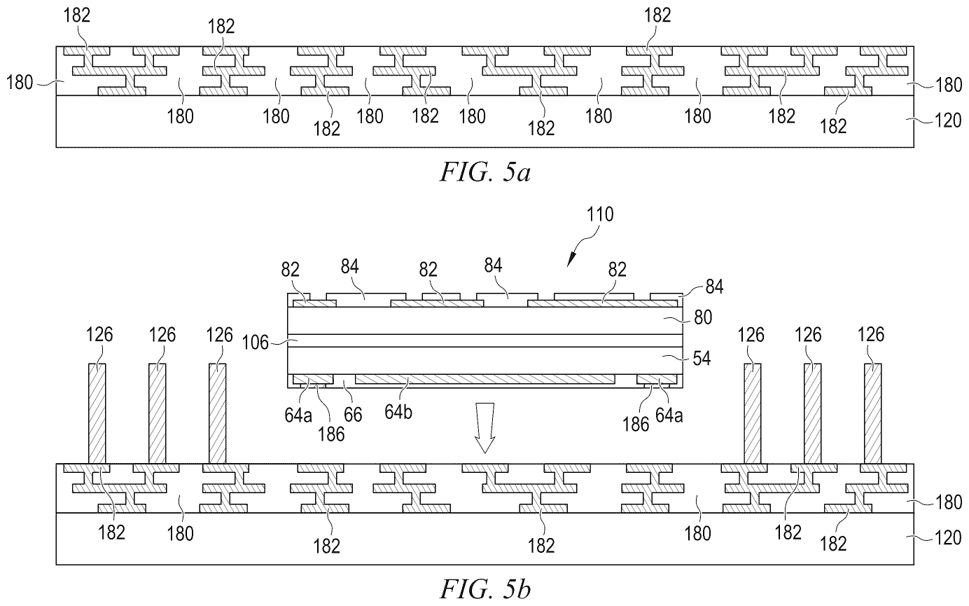

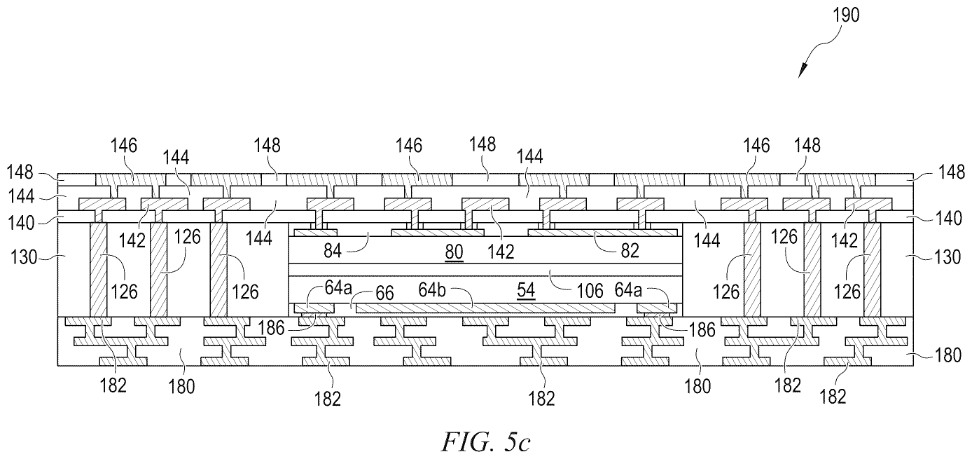

FIGS. 5a-5c illustrate an alternative process flow for forming a molded interposer with an embedded bridge module. FIG. 5a shows a substrate 180 disposed on carrier 120. Substrate 180 is a multi-layered interconnect substrate including conductive layers 182 and insulating layers 184. While only a single substrate 180 suitable to form a single unit interposer is shown, hundreds or thousands of units are commonly manufactured on a single substrate before being singulated from each other, using the same steps described herein performed en masse. A separate substrate 180 could also be used for each unit being manufactured, the substrate being singulated before the steps shown hereafter and a plurality of individual substrates being placed on a common carrier for processing.

Conductive layers 182 can be one or more layers of Al, Cu, Sn, Ni, Au, Ag, or other suitable electrically conductive material. Conductive layers 182 can be formed using PVD, CVD, electrolytic plating, electroless plating, or other suitable metal deposition process. Conductive layers 182 provide horizontal electrical interconnect across substrate 180 and vertical electrical interconnect between the top and bottom surfaces. Portions of conductive layers 182 can be electrically common or electrically isolated depending on the design and function of the package, module, or chiplet being formed.

Insulating layers 184 contain one or more layers of SiO2, Si3N4, SiON, Ta2O5, Al2O3, solder resist, PI, BCB, PBO, and other material having similar insulating and structural properties. Insulating layers 184 can be formed using PVD, CVD, printing, lamination, spin coating, spray coating, sintering, thermal oxidation, or another suitable process. Insulating layers 184 provide isolation between conductive layers 182. Any number of conductive layers 182 and insulating layers 184 can be interleaved over each other to form substrate 180.

Any other suitable type of package substrate or leadframe is used for substrate 180 in other embodiments. For example, substrate 180 can be a laminate interposer, PCB, wafer-form, strip interposer, leadframe, or another suitable substrate. Substrate 180 may include one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics. Substrate 180 can also be a multi-layer flexible laminate, ceramic, copper clad laminate, glass, or semiconductor wafer including an active surface containing one or more transistors, diodes, and other circuit elements to implement analog circuits or digital circuits.

In FIG. 5b, conductive vias 126 are formed as described above, but on contact pads of conductive layer 182 rather than directly on carrier 120. Bridge module 110 is mounted onto substrate 180 between conductive vias 126. An optional solder paste 186 is disposed in openings 67 of insulating layer 66, which is reflowed to electrically and mechanically connect the bridge die to contact pads of conductive layer 182. Bridge module 110 can alternatively be disposed with electronic component 80 oriented toward substrate 180.

In FIG. 5c, insulating layer 140, conductive layer 142, insulating layer 144, conductive layer 146, and passivation layer 148 are formed over encapsulant 130 as described above to form a build-up interconnect structure and complete molded interposer 190. Molded interposer 190 can be used in the same manner as molded interposer 160 but is formed using a pre-formed substrate on one side instead of two separate build-up interconnect structures formed on opposing sides of encapsulant 130.

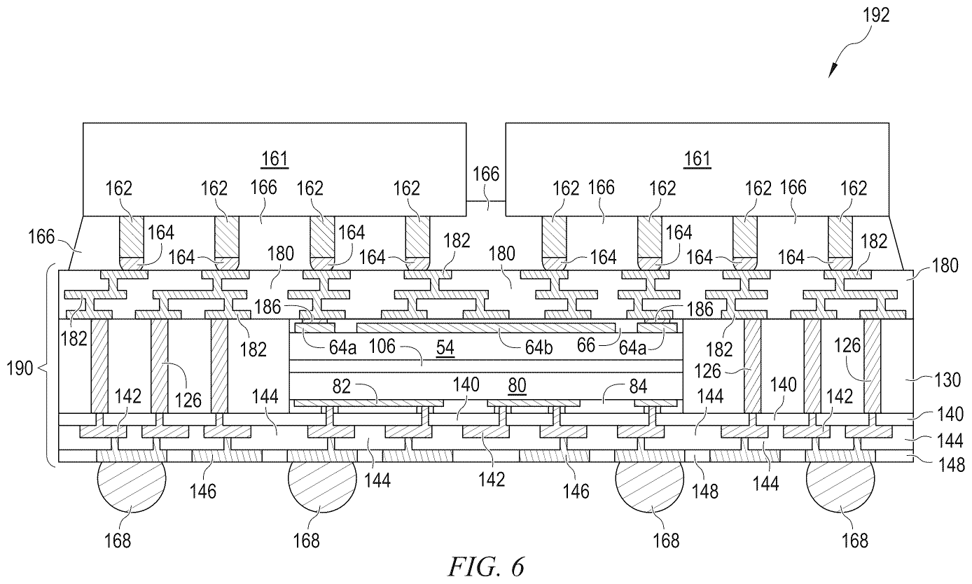

FIG. 6 illustrates a chiplet 192 formed with molded interposer 190. Semiconductor die 161 are mounted onto substrate 180 opposite bridge module 110, but otherwise chiplet 192 is formed as described above for chiplet 170.

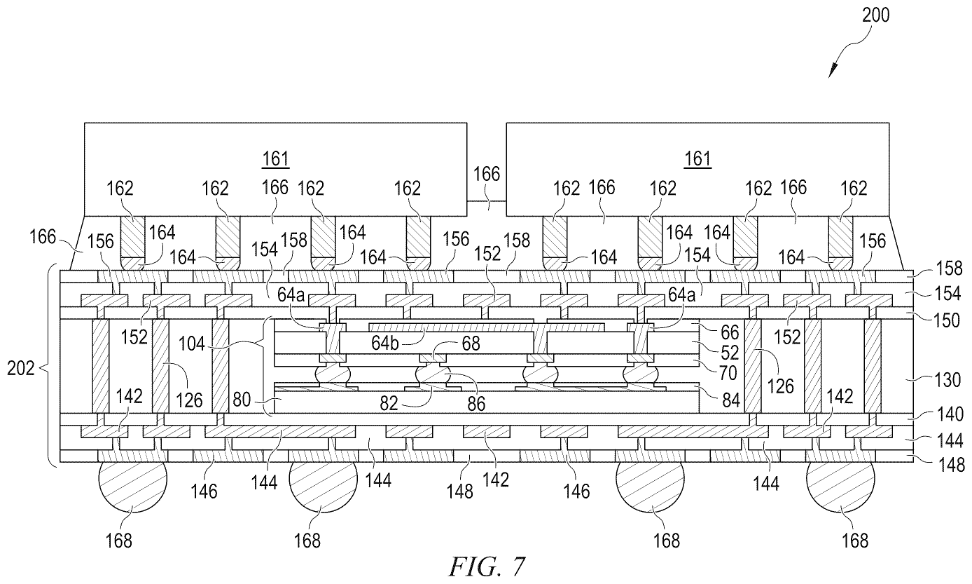

FIG. 7 illustrates a chiplet 200 formed with bridge module 104 embedded in molded interposer 202. Bridge module 104 has electrical component 80 connected through conductive vias 64c of bridge die 54 to conductive layers 152 and 156 rather than directly to conductive layers 142 and 146 as in the previous embodiments. Otherwise, molded interposer 202 is formed the same as molded interposer 160 and chiplet 200 is formed the same as chiplet 170. Bridge module 104 can also be used with the alternative embodiment from FIGS. 5a-5c where conductive vias 126 are formed on pre-formed substrate 180.

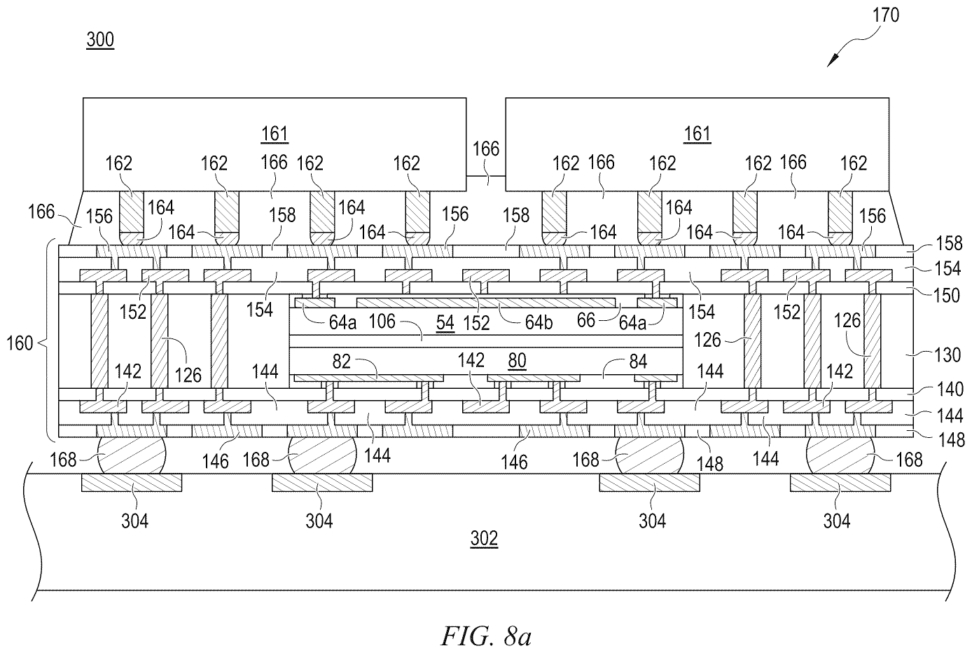

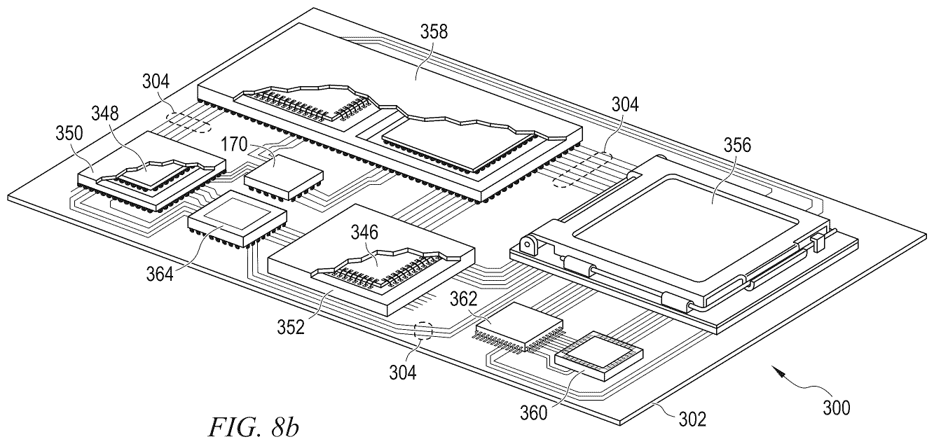

FIGS. 8a and 8b illustrate integrating the above-described semiconductor packages, e.g., chiplet 170, into a larger electronic device 300. FIG. 8a illustrates a partial cross-section of chiplet 170 mounted onto a printed circuit board (PCB) or other substrate 302 as part of electronic device 300. Solder bumps 168 are reflowed onto conductive layer 304 of PCB 302 to physically attach and electrically connect chiplet to the PCB. In other embodiments, thermocompression or another suitable attachment and connection methods are used. In some embodiments, an adhesive or underfill layer is used between chiplet 170 and PCB 302. Semiconductor die 161 are electrically coupled to conductive layer 304 through the conductive layers of molded interposer 160. Molded interposer 160 also includes bridge module 110 that electrically couples the two semiconductor die 161 to each other. In addition, bridge module 110 includes additional active and/or passive electrical components 80 to supplement the functionality of semiconductor die 170. Integrating bridge die 54 with electrical component 80, or other additional electrical components, increases the level of integration, reducing device size, manufacturing complexity, and cost.

FIG. 8b illustrates electronic device 300 having a chip carrier substrate or PCB 302 with a plurality of semiconductor packages disposed on a surface of PCB 302, including chiplet 170. Electronic device 300 can have one type of semiconductor package, or multiple types of semiconductor packages, depending on the application. In other embodiments, chiplet 170 is incorporated as only one part of another larger semiconductor package, e.g., a system-in-package, before being incorporated into a larger electronic device 300.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 8b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a bridge die;
mounting an electrical component to the bridge die to form a bridge module;
disposing the bridge module over a carrier;
forming a conductive via over the carrier;
depositing an encapsulant over the conductive via and bridge module;
forming a first conductive layer over the encapsulant, conductive via, and bridge module;
removing the carrier; and
forming a second conductive layer over the encapsulant, conductive via, and bridge module opposite the first conductive layer.

2. The method of claim 1, further including disposing a first semiconductor die and second semiconductor die over the bridge module and encapsulant, wherein the first semiconductor die is coupled to the second semiconductor die through the bridge die.

3. The method of claim 2, further including forming a solder bump over the bridge die and encapsulant opposite the first semiconductor die and second semiconductor die.

4. The method of claim 1, further including a solder bump disposed between the electrical component and bridge die.

5. The method of claim 4, further including forming a second conductive via through the bridge die, wherein the electrical component is coupled to the first conductive layer or second conductive layer through the solder bump and second conductive via after mounting the electrical component to the bridge die.

6. The method of claim 1, further including disposing an adhesive layer between the electrical component and bridge die.

7. A method of making a semiconductor device, comprising:
providing a bridge die;
mounting an electrical component to the bridge die to form a bridge module;
depositing an encapsulant over the bridge module;
forming a first conductive layer over the encapsulant and bridge module; and
forming a second conductive layer over the encapsulant and bridge module opposite the first conductive layer.

8. The method of claim 7, further including disposing a first semiconductor die and second semiconductor die over the first conductive layer, wherein the first semiconductor die is coupled to the second semiconductor die through the bridge die and first conductive layer.

9. The method of claim 8, further including forming a solder bump over the bridge die and encapsulant opposite the first semiconductor die and second semiconductor die.

10. The method of claim 7, further including disposing a solder bump between the electrical component and bridge die.

11. The method of claim 10, further including forming a conductive via through the bridge die, wherein the electrical component is coupled to the first conductive layer or second conductive layer through the solder bump and conductive via after mounting the electrical component to the bridge die.

12. The method of claim 7, further including disposing an adhesive layer between the electrical component and bridge die.

13. The method of claim 7, further including providing a conductive via extending through the encapsulant to electrically connect the first conductive layer to the second conductive layer.

14. A semiconductor device, comprising:
a bridge module comprising a bridge die and an electrical component mounted to the bridge die;
a conductive via disposed adjacent to the bridge module;
an encapsulant deposited over the conductive via and bridge module;
a first conductive layer formed over the encapsulant, conductive via, and bridge module; and
a second conductive layer formed over the encapsulant, conductive via, and bridge module opposite the first conductive layer.

15. The semiconductor device of claim 14, further including a first semiconductor die and second semiconductor die disposed over the bridge module and encapsulant, wherein the first semiconductor die is coupled to the second semiconductor die through the bridge die.

16. The semiconductor device of claim 15, further including a solder bump formed over the bridge die and encapsulant opposite the first semiconductor die and second semiconductor die.

17. The semiconductor device of claim 14, further including a solder bump disposed between the electrical component and bridge die.

18. The semiconductor device of claim 17, further including a second conductive via formed through the bridge die, wherein the electrical component is coupled to the first conductive layer or second conductive layer through the solder bump and second conductive via.

19. The semiconductor device of claim 14, further including an adhesive layer disposed between the electrical component and bridge die.

20. A semiconductor device, comprising:
a bridge module comprising a bridge die and an electrical component mounted to the bridge die;
an encapsulant deposited over the bridge module;
a first conductive layer disposed over the encapsulant and bridge module; and
a second conductive layer disposed over the encapsulant and bridge module opposite the first conductive layer.

21. The semiconductor device of claim 20, further including a first semiconductor die and second semiconductor die disposed over the first conductive layer, wherein the first semiconductor die is coupled to the second semiconductor die through the bridge die.

22. The semiconductor device of claim 20, wherein the first conductive layer is part of a substrate.

23. The semiconductor device of claim 20, further including a solder bump disposed between the electrical component and bridge die.

24. The semiconductor device of claim 23, further including a conductive via formed through the bridge die, wherein the electrical component is coupled to the first conductive layer or second conductive layer through the solder bump and conductive via.

25. The semiconductor device of claim 20, further including an adhesive layer disposed between the electrical component and bridge die.
